(19) United States
(12) Patent Application Publication
(10) Pub. No.: US 2025/0201632 A1
(43) Pub. Date: Jun. 19, 2025

(54) METHOD FOR MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Yuji NAGUMO, Nisshin-shi (JP); Masashi UECHA, Nisshin-shi (JP); Masaru OKUDA, Nisshin-shi (JP); Masatake NAGAYA, Nisshin-shi (JP)

(21) Appl. No.: 18/948,662

(22) Filed: Nov. 15, 2024

(30) Foreign Application Priority Data
Dec. 19, 2023 (JP) 2023-214219

(51) Int. Cl. H01L 21/78; H01L 21/304; H01L 21/683

(52) U.S. Cl. CPC H01L 21/78; H01L 21/304; H01L 21/6836; H01L 2221/68327

(57) ABSTRACT

A method for manufacturing a semiconductor device, includes: preparing a semiconductor wafer having a crystal axis inclined relative to a perpendicular line to a first surface; forming a first crack in the semiconductor wafer along a first direction and in a thickness direction by pressing a pressing member against the first surface with a first load and along the first direction, the first direction being along an inclined direction of the crystal axis on the first surface; forming a second crack in the semiconductor wafer along a second direction perpendicular to the first direction and in the thickness direction by pressing the pressing member against the first surface with a second load smaller than the first load along the second direction; and dividing the semiconductor wafer along the first crack and the second crack by pressing a dividing member against the semiconductor wafer from a second surface side.

### CROSS REFERENCE TO RELATED APPLICATION

The present application claims the benefit of priority from Japanese Patent Application No. 2023-214219 filed on Dec. 19, 2023. The entire disclosures of the above application are incorporated herein by reference.

### TECHNICAL FIELD

The present disclosure relates to a method for manufacturing a semiconductor device.

### BACKGROUND

As a technique for dividing a substrate, there has been known a scribe and break method. In the known scribe and break method for the substrate, a pressing member is pressed against a surface of the substrate along a first direction so as to form a crack extending along the first direction in the substrate. After the crack extending along the first direction is formed, the pressing member is pressed against the surface of the substrate along a second direction intersecting the first direction so as to form a crack extending along the second direction in the substrate. Thereafter, a dividing member is pressed against the substrate, thereby to divide the substrate along the formed cracks.

### SUMMARY

The present disclosure describes a method for manufacturing a semiconductor device, which reduces residual stress caused by forming of cracks in a semiconductor wafer. According to an aspect, a method for manufacturing a semiconductor device includes: preparing a semiconductor wafer having a first surface and a second surface opposite to the first surface in a thickness direction of the semiconductor wafer, the semiconductor wafer having a crystal axis inclined relative to a perpendicular line to the first surface; forming a first crack in the semiconductor wafer to extend along a first direction and in the thickness direction by pressing a pressing member against the first surface with a first load and along the first direction, the first direction being along an inclined direction of the crystal axis on the first surface; forming a second crack in the semiconductor wafer to extend along a second direction perpendicular to the first direction and in the thickness direction by pressing the pressing member against the first surface with a second load smaller than the first load and along the second direction; and dividing the semiconductor wafer along the first crack and the second crack by pressing a dividing member against the semiconductor wafer on a second surface side in the thickness direction and along the first crack and the second crack.

### BRIEF DESCRIPTION OF THE DRAWINGS

Objects, features and advantages of the present disclosure will become more apparent from the following detailed description made with reference to the accompanying drawings, in which like parts are denoted by like reference numbers and in which:

FIG. 1 is a diagram illustrating a plan view of a semiconductor wafer;

FIG. 2 is a diagram for explaining a crystal structure of silicon carbide (SIC);

FIG. 3 is a diagram for explaining an element structure forming process;

FIG. 4 is a diagram for explaining a support plate attaching process;

FIG. 5 is a diagram for explaining a crack forming process;

FIG. 6A is a diagram illustrating a scanning electron microscope image of a cross section along a y-z plane of a semiconductor wafer in which a crack has been formed;

FIG. 6B is a diagram illustrating a scanning electron microscope image of a cross section along a x-z plane of the semiconductor wafer in which the crack has been formed;

FIG. 7 is a diagram for explaining a metal film forming process;

FIG. 8 is a diagram for explaining a dicing tape attaching process;

FIG. 9 is diagram for explaining a support plate detaching process;

FIG. 10 is a diagram for explaining a protective member covering process;

FIG. 11 is a diagram for explaining a dividing process;

FIG. 12 is a diagram for explaining a pickup process;

FIG. 13A is a graph illustrating residual stresses measured in a direction extending from a first surface to a second surface of a semiconductor device in a comparative example; and

FIG. 13B is a graph illustrating residual stresses measured in a direction extending from a first surface to a second surface of a semiconductor device according to an embodiment.

### DETAILED DESCRIPTION

To begin with, a relevant technology will be described only for understanding the embodiments of the present disclosure.

As a relevant technology, there has been known a scribe and break method for a substrate, in which a pressing member is pressed against the surface of the substrate along a first direction so as to form a crack extending along the first direction in the substrate, and after the crack extending along the first direction is formed, the pressing member is pressed against the surface of the substrate along a second direction intersecting the first direction so as to form a crack extending along the second direction in the substrate. Thereafter, a dividing member is pressed against the substrate so as to divide the substrate along the formed cracks.

In the scribe and break method for the substrate described above, the load with which the pressing member is pressed against the surface of the substrate to form the crack along the first direction is greater than the load with which the pressing member is pressed against the surface of the substrate to form the crack along the second direction. Therefore, it is possible to suppress defects, such as chipping, in the substrate near the intersection of the crack along the first direction and the crack along the second direction.

In recent years, the scribe and break method is adopted for dividing a semiconductor wafer. A semiconductor wafer may have a crystal axis that is inclined relative to a perpendicular line to a surface of the semiconductor wafer. The crack tends to be formed along the crystal axis inside the semiconductor wafer, with respect to the thickness direction of the semiconductor wafer. In a case of forming a crack along a direction intersecting the inclined direction of the crystal axis, the formed direction of the crack in the semiconductor wafer with respect to the thickness direction (i.e., the direction inclined relative to the perpendicular line) is inclined relative to the pressing direction by the pressing member against the surface of the semiconductor wafer (i.e., the direction along the perpendicular line), resulting in the stress being generated inside the semiconductor wafer. That is, the magnitude of the stress generated inside the semiconductor wafer varies depending on the direction in which the crack is formed. As a result, even after the semiconductor wafer is divided, the stress is likely to remain as residual stress, and the characteristics of semiconductor devices manufactured by using the semiconductor wafer will be deteriorated. The present disclosure provides a technique for reducing residual stresses resulting from the formation of cracks in a semiconductor wafer.

According to an aspect of the present disclosure, a method for manufacturing a semiconductor device includes preparing a semiconductor wafer, forming a first crack in the semiconductor wafer, forming a second crack in the semiconductor wafer, and dividing the semiconductor wafer. In the preparing, a semiconductor wafer having a first surface and a second surface opposite to the first surface in a thickness direction of the semiconductor wafer, and having a crystal axis inclined relative to a perpendicular line to the first surface is prepared. In the forming of the first crack; a pressing member is pressed against the first surface with a first load along a first direction that is along an inclined direction of the crystal axis on the first surface, thereby to form the first crack in the semiconductor wafer extending along the first direction and in the thickness direction. In the forming of the second crack, the pressing member is pressed against the first surface with a second load smaller than the first load and along a second direction perpendicular to the first direction on the first surface, thereby to form the second crack in the semiconductor wafer extending along the second direction and in the thickness direction. In the dividing of the semiconductor wafer, a dividing member is pressed against the semiconductor wafer on a second surface side along the first crack and the second crack, thereby to divide the semiconductor wafer along the first crack and the second crack. Note that either the forming of the first crack and the forming of the second crack may be carried out first.

In the method described above, since the first direction is along the inclined direction of the crystal axis, when the first crack is formed along the first direction, the formed direction of the first crack with respect to the thickness direction of the semiconductor wafer approximately coincides with the pressing direction by the pressing member. Therefore, the stress generated inside the semiconductor wafer due to the formation of the first crack is small. On the other hand, since the second direction is orthogonal to the inclined direction of the crystal axis, when the second crack is formed along the second direction, the formed direction of the second crack with respect to the thickness direction of the semiconductor wafer is inclined with respect to the pressing direction by the pressing member. Therefore, the stress generated inside the semiconductor wafer due to the formation of the second crack increases. However, in the manufacturing method described above, the second load of the pressing member when forming the second crack is smaller than the first load of the pressing member when forming the first crack. Therefore, when the second crack is formed, the stress caused by the difference between the formed direction of the second crack and the pressing direction of the pressing member is reduced. As a result, residual stress in the entire semiconductor device after the semiconductor wafer is divided is reduced, and a highly reliable semiconductor device can be manufactured.

According to an aspect, the method may further include forming a plurality of element structures in a matrix on the second surface of the semiconductor wafer prior to the forming of the first crack and the forming of the second crack. Also, in the forming of the first crack and the forming of the second crack, the first crack and the second crack may be formed along the boundary of the element structures.

When the cracks are formed, stress is likely to occur in the vicinity of the surface against which the pressing member is pressed. According to the method described above, the pressing member is not pressed from the second surface side on which the element structures are provided, but is pressed from the first surface side, which is on the side opposite to the first side. Therefore, even if the residual stress exists in the vicinity of the first surface, the influence on the element structures that realize the functions of the semiconductor device can be reduced.

According to an aspect of the present disclosure, the method may further include forming a metal film on the first surface, after the forming of the first crack and the forming of the second crack, and before the dividing of the semiconductor wafer.

In such a method, the metal film formed on the first surface can function as an electrode of the semiconductor device.

According to an aspect of the present disclosure, in the method, the semiconductor wafer may be made of silicon carbide (SiC). Further, in the method, the crystal axis may be a c-axis.

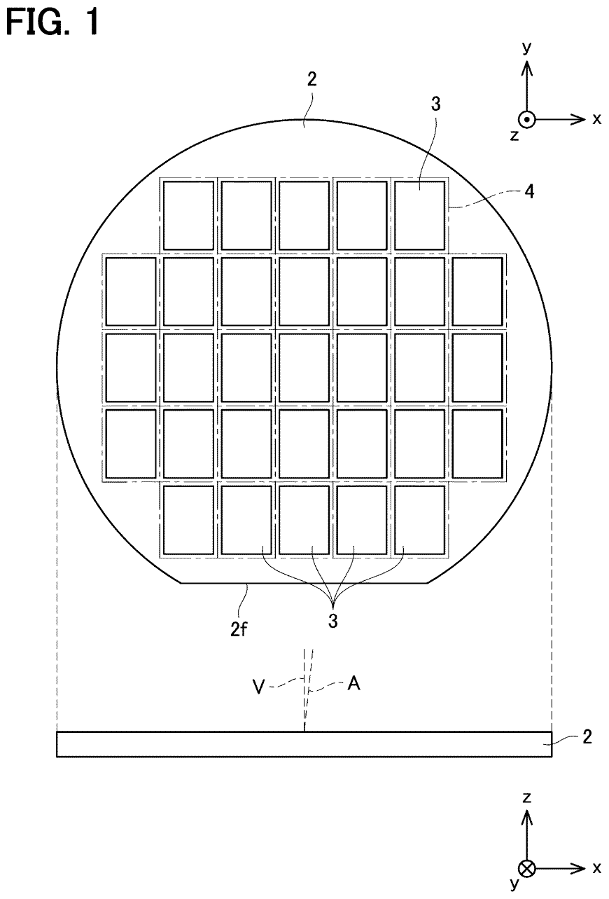

Hereinafter, an embodiment of the present disclosure will be described with reference to the drawings. FIG. 1 shows a plan view of a semiconductor wafer 2 used to manufacture semiconductor devices. The semiconductor wafer 2 has a disk shape.

The semiconductor wafer 2 has an orientation flat 2f on the outer peripheral surface thereof. The semiconductor wafer 2 is provided with a plurality of element regions 3 arranged in a matrix. In FIG. 1, each of the element regions 3 is schematically illustrated by a solid line. The element region 3 is a region where an element structure such as a transistor or a diode is formed. For convenience of description, division lines that are boundaries between adjacent element regions 3 and that are used when the semiconductor wafer 2 is divided into individual element regions 3 are referred to as planned dividing lines 4. The planned dividing lines 4 are not actually drawn on the semiconductor wafer 2 but are virtual lines. The planned dividing lines 4 may be lines or grooves actually drawn on the semiconductor wafer 2 so as to be visible. The semiconductor wafer 2 is made of silicon carbide (SiC). The semiconductor wafer 2 may be made of another semiconductor material, such as silicon (Si) or gallium nitride (GaN). As shown in FIG. 3 and the like, the semiconductor wafer 2 has a first surface 2a and a second surface 2b located opposite to the first surface 2a in a thickness direction of the semiconductor wafer 2.

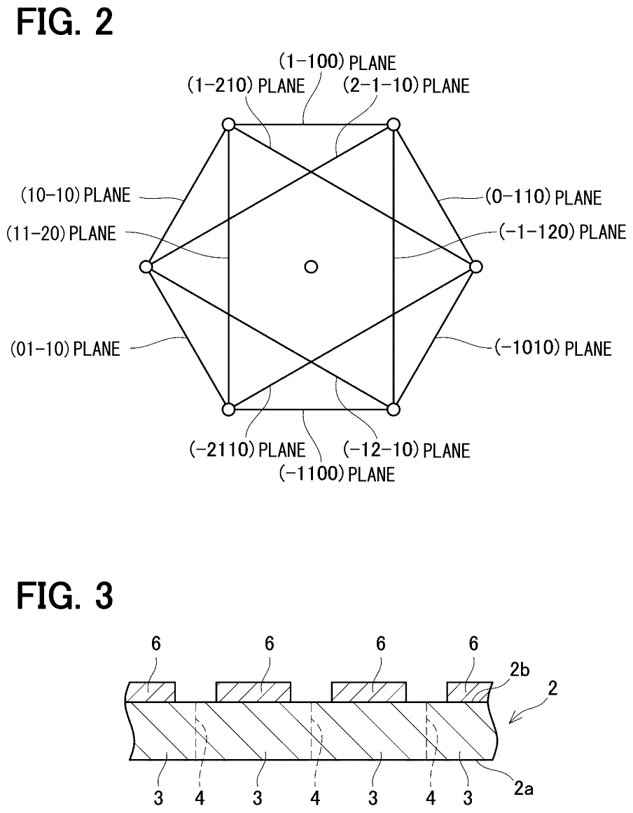

The semiconductor wafer 2 has a hexagonal crystal structure as shown in FIG. 2. As shown in FIG. 2, the semiconductor wafer 2 has multiple crystal planes. Although not shown, a plane parallel to a surface of a paper on which FIG. 2 is illustrated is a (0001) plane. In the present embodiment, as shown in FIG. 1, a crystal axis A of SiC (i.e., the c-axis) is inclined in the x direction by about 4° relative to the z direction (i.e., the perpendicular line V that is perpendicular to the second surface 2b of the semiconductor wafer 2). The crystal axis A is not inclined in the y direction relative to the perpendicular line V. That is, the crystal axis A is inclined relative to the perpendicular line V within the x-z plane. In other words, in the present embodiment, the (0001) plane (i.e., the c-plane) is inclined in the x direction by about 4° relative to the second surface 2b of the semiconductor wafer 2, the (1-100) plane is a plane parallel to the orientation flat 2f, and the (11-20) plane is inclined in the x direction by about 4° relative to a plane perpendicular to the orientation flat 2f.

The manufacturing method of the present embodiment includes an element structure forming process, a support plate attaching process, a first crack forming process, a second crack forming process, a metal film forming process, a dicing tape attaching process, a support plate detaching process, a protective member covering process, and a dividing process.

### (Element Structure Forming Process)

In the element structure forming process, as shown in FIG. 3, the multiple element structures 6 are formed on the second surface 2b of the semiconductor wafer 2. The element structure 6 includes at least one of an electrode, an insulating film, an n-type region, and a p-type region provided on the second surface 2b side. The element structure 6 include structures for realizing the functions of a semiconductor device, such as a trench and a gate electrode. In this process, the element structure 6 is individually formed for each element region 3. Therefore, the element structures 6 are formed on the second surface 2b of the semiconductor wafer 2 so as to be arranged in a matrix. In this process, the element structures 6 are formed, as well as structures (not shown) having the functions of a transistor or a diode are also formed inside the semiconductor wafer 2 in each element region 3. For example, in a case where a metal oxide semiconductor field effect transistor (MOSFET) structure is formed inside the semiconductor wafer 2, a source region and a body region are formed for each element structure 6 individually, in a region exposed on the second surface 2b. On the other hand, in a region exposed on the first surface 2a, a drain region is formed over substantially the entire area of the first surface 2a. That is, the drain region is formed so as to extend over the multiple element regions 3 at a position exposed on the first surface 2a.

### (Support Plate Attaching Process)

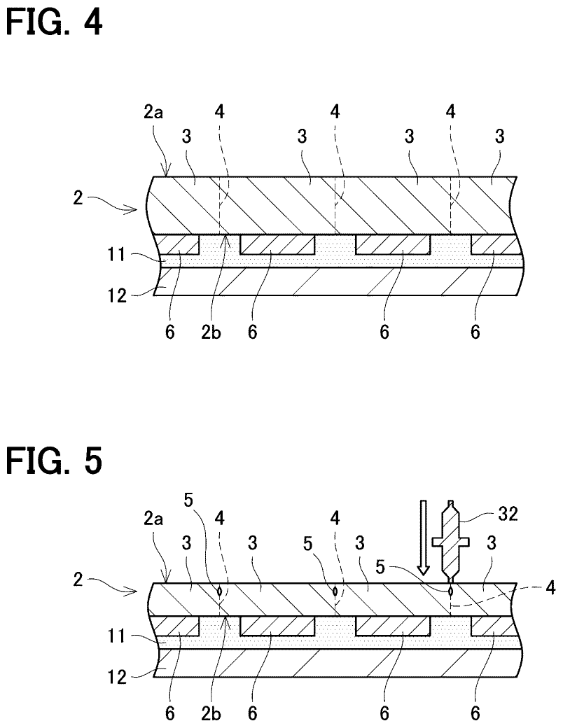

In the support plate attaching process, as shown in FIG. 4, a support plate 12 is attached to the second surface 2b of the semiconductor wafer 2. The support plate 12 is attached to the second surface 2b through an adhesive 11. The support plate 12 is made of, for example, glass. The adhesive 11 is, for example, a silicon-based adhesive. In addition to the function of adhering the semiconductor wafer 2 to the support plate 12, the adhesive 11 has the function of protecting the element structures 6 formed on the second surface 2b of the semiconductor wafer 2. In this case, therefore, the adhesive 11 is applied so that the thickness of the adhesive 11 is greater than the thickness of the element structures 6. Thereafter, if necessary, the first surface 2a of the semiconductor wafer 2 is ground with a grinding wheel to thin the semiconductor wafer 2. It should be noted that, in FIGS. 4 and 5, the semiconductor wafer 2 is illustrated with the first surface 2a facing up.

### (First Crack Forming Process)

After the semiconductor wafer 2 has been thinned, the first crack forming process is performed, as shown in FIG. 5. In the first crack forming process, a scribing wheel 32 is pressed against the first surface 2a of the semiconductor wafer 2, which has been attached to the support plate 12, so that a scribe line accompanied by a crack 5 inside the semiconductor wafer 2 is formed. The scribing wheel 32 is a disk-shaped (annular) member, and is axially supported by a supporting device (not shown). In this process, the scribing wheel 32 is moved (scanned) along each of the planned dividing lines 4 extending along the x direction in FIG. 1 while being pressed against the first surface 2a of the semiconductor wafer 2. When moving along the planned dividing line 4, the scribing wheel 32 rolls on the first surface 2a of the semiconductor wafer 2 without slipping, like a tire rolling on a road surface. Although the scribing wheel 32 has a sharp peripheral edge, the scribing wheel 32 is simply pressed against the first surface 2a without cutting the semiconductor wafer 2. In the first crack forming process, the scribing wheel 32 is pressed against the first surface 2a with the load of about 2.0 N. When the first surface 2a is pressed by the scribing wheel 32, a compressive stress is generated inside the semiconductor wafer 2 in a surface layer region adjacent to the first surface 2a. While the scribe line (i.e., a groove) is formed at a position pressed by the scribing wheel 32, a tensile stress is generated in the semiconductor wafer 2 immediately below the region where the compressive stress is generated. The tensile stress is generated in a direction away from the planned dividing line 4 along the first surface 2a of the semiconductor wafer 2 immediately below the region where the compressive stress is generated. This tensile stress causes a crack 5 to be formed inside the semiconductor wafer 2, the crack 5 extending along the x direction and in the thickness direction of the semiconductor wafer 2. In this case, by pressing the scribing wheel 32 against the first surface 2a and moving it along the planned dividing line 4 along the x direction, the crack 5 is formed so as to extend along the boundary between the element regions 3 adjacent in the y direction and in the thickness direction of the semiconductor wafer 2. The crack 5 is formed in the vicinity of the surface layer of the first surface 2a of the semiconductor wafer 2. The scribing wheel 32 is an example of a “pressing member”.

### (Second Crack Forming Process)

Next, the second crack forming process is performed. In the second crack forming process, the scribing wheel 32 is moved (scanned) along each of the planned dividing lines 4 extending along the y direction in FIG. 1 while being pressed against the first surface 2a of the semiconductor wafer 2. This process is the same as the first crack forming process, except for the direction in which the scribing wheel 32 is moved (scanned) and the load with which the scribing wheel 32 is pressed against the first surface 2a being about 1.5 N.

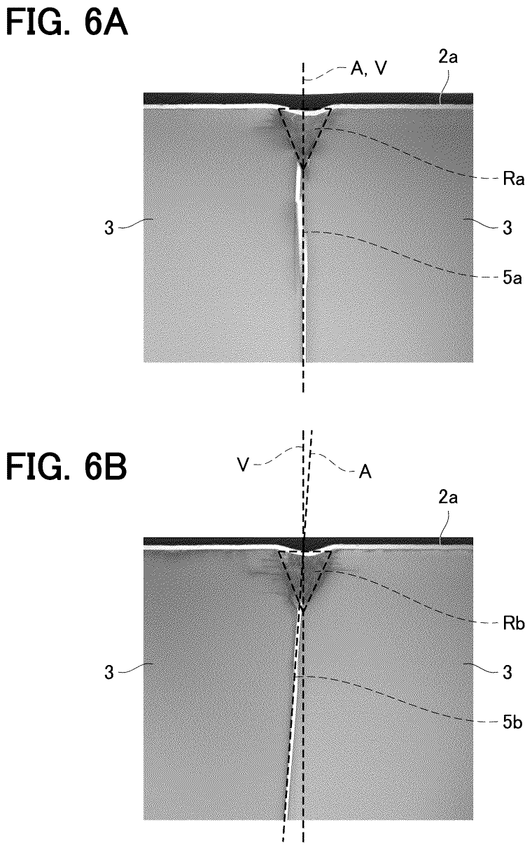

FIG. 6A and FIG. 6B are scanning electron microscope images of a cross section of the semiconductor wafer 2 after the crack 5 has been formed by the scribing wheel 32. FIG. 6A shows a cross section of the semiconductor wafer 2 defined along the y-z plane near the first surface 2a, and FIG. 6B shows a cross section of the semiconductor wafer 2 defined along the x-z plane near the first surface 2a. As shown in FIGS. 6A and 6B, it is apparent that first and second cracks 5 and 5b are formed inside the semiconductor wafer 2 along the boundary between the element regions 3 by pressing the scribing wheel 32 along the planned dividing lines 4. Also, the first surface 2a of the semiconductor wafer 2 is observed to have the scribe line that is slightly depressed due to the plastic deformation of the semiconductor wafer 2 caused by the scribing wheel 32. As shown in FIG. 6A, in the y-z cross section, the crystal axis A of SiC is not inclined relative to the perpendicular line V to the first surface 2a, so the first crack 5a is formed to extend in a direction that is substantially the same as the pressing direction of the scribing wheel 32, with respect to the thickness direction of the semiconductor wafer 2. On the other hand, as shown in FIG. 6B, in the x-z cross section, the crystal axis A of SiC is inclined relative to the perpendicular line V to the first surface 2a, so the second crack 5b is formed to extend in a direction inclined relative to the pressing direction of the scribing wheel 32, with respect to the thickness direction of the semiconductor wafer 2.

### (Metal Film Forming Process)

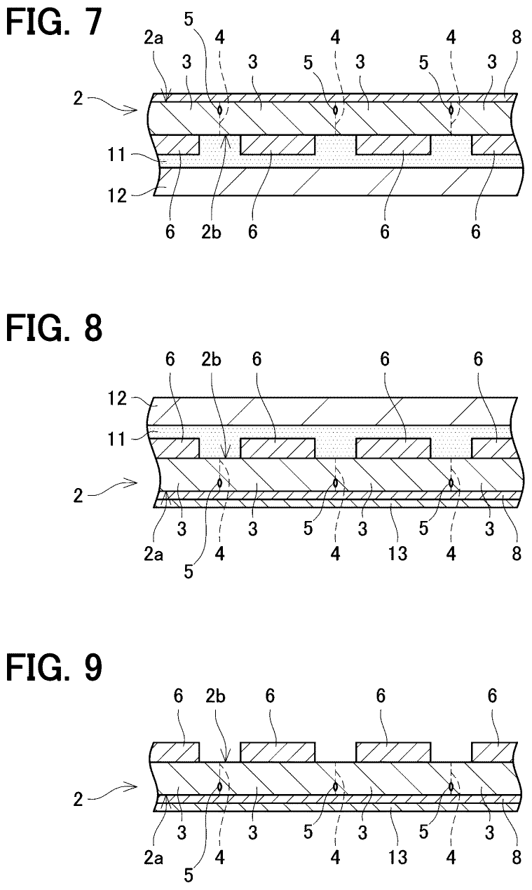

Next, the metal film forming process shown in FIG. 7 is performed. In the metal film forming process, a metal film 8 is formed on the first surface 2a of the semiconductor wafer 2. Although the material forming the metal film 8 is not particularly limited, the metal film 8 may be, for example, made of a multi-layer film in which aluminum, nickel, and gold are laminated. The metal film 8 is formed so as to cover substantially the entire region of the first surface 2a. That is, the metal film 8 is formed on the first surface 2a so as to extend over the element regions 3. The metal film 8 functions as an electrode in the manufactured semiconductor device.

### (Dicing Tape Attaching Process)

Next, the dicing tape attaching process shown in FIG. 8 is performed. In the dicing tape attaching process, a dicing tape 13 is attached to a surface of the metal film 8. The dicing tape 13 is attached so as to cover substantially the entire region of the metal film 8. The dicing tape 13 is fixed to a dicing frame (not shown). It should be noted that, in FIG. 8 and subsequent figures, the semiconductor wafer 2 is again illustrated with the second surface 2b facing up.

### (Support Plate Detaching Process)

Next, the support plate detaching process shown in FIG. 9 is performed. In the support plate detaching process, the support plate 12 and the adhesive 11 are peeled off from the second surface 2b of the semiconductor wafer 2. For example, by dissolving the adhesive 11 with a solvent, the support plate 12 is separated from the second surface 2b together with the adhesive 11. As a result, the semiconductor wafer 2 is in a state of being supported by the dicing tape 13.

### (Protective Member Covering Process)

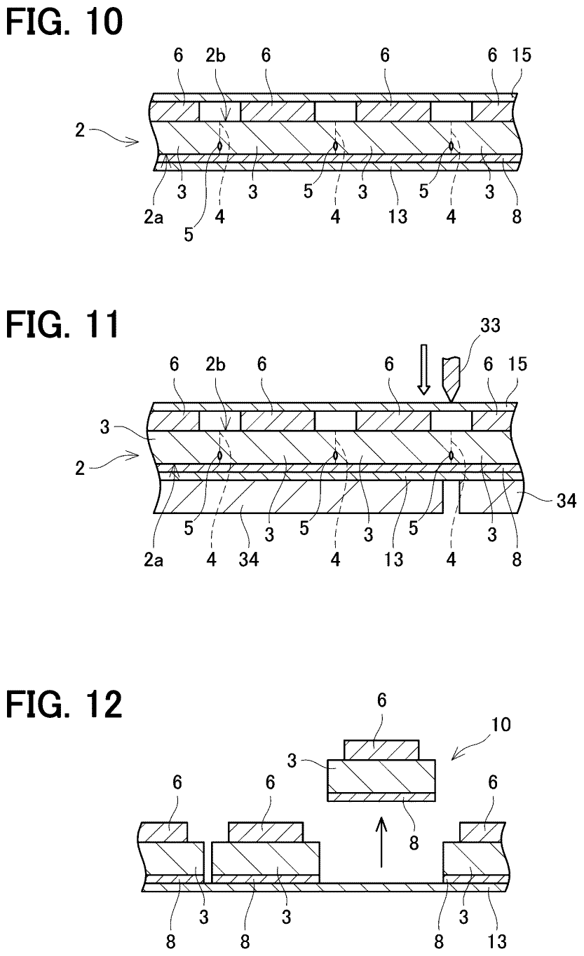

Next, the protective member covering process shown in FIG. 10 is performed. In the protective member covering process, a protective member 15 is attached so as to extend over the surfaces of the element structures 6 in the respective element regions 3 of the semiconductor wafer 2, so that the second surface 2b of the semiconductor wafer 2 is covered with the protective member 15. Although the material of the protective member 15 is not particularly limited, the protective member 15 may be, for example, made of a resin or the like. By covering the second surface 2b of the semiconductor wafer 2 with the protective member 15, the second surface 2b is protected during the subsequent dividing process and the like.

### (Dividing Process)

Next, the dividing process shown in FIG. 11 is performed. In the dividing process, a breaking plate 33 is pressed along the planned dividing line 4 to divide the semiconductor wafer 2 along the planned dividing line 4 (i.e., along the boundary between the element regions 3). In this case, firstly, the semiconductor wafer 2 is placed on two support bases 34. The two support bases 34 are spaced apart from each other so as to have a gap therebetween. The semiconductor wafer 2 is placed on the support bases 34 so that the gap is located below the position where the semiconductor wafer 2 is to be divided, that is, the gap is located below the position where the breaking plate 33 is pressed against. Thereafter, the breaking plate 33 is pressed against the semiconductor wafer 2 via the protective member 15 on the second surface 2b side. The breaking plate 33 is a plate-like member. A lower end of the breaking plate 33 (i.e., an end edge pressed against the second surface 2b) has a ridgeline shape (i.e., a sharp edge shape), but is only pressed against the semiconductor wafer 2 without cutting the semiconductor wafer 2.

The support bases 34 are not present below the breaking plate 33, that is, the gap between the two support bases 34 is located below the breaking plate 33. Therefore, when the breaking plate 33 is pressed against the second surface 2b, the semiconductor wafer 2 is bent so as to enter the gap between the two support bases 34. In this case, the cracks 5 are formed adjacent to the first surface 2a of the semiconductor wafer 2. Therefore, when the breaking plate 33 is pressed against the semiconductor wafer 2 on the second surface 2b side, the semiconductor wafer 2 is bent about the pressed portion (line). Thus, in a region close to the first surface 2a, a force is generated in the crack 5 in directions separating the two element regions 3, which are adjacent across the crack 5 as a dividing position. As described above, the tensile stress has been applied to the periphery of the crack 5. Therefore, when the breaking plate 33 is pressed against the second surface 2b, the crack 5 extends in the thickness direction of the semiconductor wafer 2, and the semiconductor wafer 2 is cleaved along the crystal plane starting from the crack 5. As a result, the semiconductor wafer 2 is divided. In addition, since the metal film 8 has been formed on the first surface 2a of the semiconductor substrate 2, a force is also applied to the metal film 8 in directions in which the two element regions 3 adjacent to the dividing position are separated, and thus the metal film 8 is deformed and divided so as to be separated. Instead of the two support bases 34, the entire first surface 2a of the semiconductor wafer 2 may be supported by one elastic support plate, or by one or more support bases via one elastic support plate. In this case, although the elastic support plate is present below the breaking plate 33, when the semiconductor wafer 2 is bent, the elastic support plate is deformed according to the bending of the semiconductor wafer 2. Therefore, when the breaking plate 33 is pressed against the second surface 2b, a force is applied to the crack 5 in a direction in which the two element regions 3 adjacent to the dividing position are separated from each other, as in the case where the semiconductor substrate 2 is supported by the two support bases 34 (i.e., the case where the support bases 34 are not present below the breaking plate 33). The breaking plate 33 is an example of a “dividing member”.

In the dividing process, the process of pressing the breaking plate 33 against the second surface 2b is repeatedly performed along each planned dividing line 4. As a result, it is possible to divide the semiconductor wafer 2 and the metal film 8 along the boundaries between the element regions 3. Thereafter, as shown in FIG. 12, the divided element region 3 with the metal film 8 is separated from the dicing tape 13. Accordingly, the multiple semiconductor devices 10 each having the metal film 8 (electrode) on the surface are produced.

As described above, in the manufacturing method of the present embodiment, the x direction is along the inclined direction of the crystal axis. Therefore, when the first crack 5a is formed along the x direction, the formed direction of the first crack 5a (i.e., the extension direction of the crystal axis A in FIG. 6A) with respect to the thickness direction of the semiconductor wafer 2 substantially coincides with the pressing direction by the scribing wheel 32 (i.e., the extension direction of the perpendicular line V in FIG. 6A). Therefore, the stress generated inside the semiconductor wafer 2 due to the formation of the first crack 5a is small. On the other hand, the y direction is perpendicular to the inclined direction of the crystal axis. As such, when the second crack 5b is formed along the y direction, the formed direction of the second crack 5b (i.e., the extension direction of the crystal axis A in FIG. 6B) with respect to the thickness direction of the semiconductor wafer 2 is inclined relative to the pressing direction by the scribing wheel 32 (i.e., the extension direction of the perpendicular line V in FIG. 6B). Therefore, the stress generated inside the semiconductor wafer 2 due to the formation of the second crack 5b is large. These stresses remain as residual stresses even after the semiconductor wafer 2 is divided. If the residual stress exists, when the manufactured semiconductor device is repeatedly operated, a load is likely to be applied in the vicinity of the region where the residual stress exists, and the reliability of the semiconductor device is reduced.

In the manufacturing method of the present embodiment, therefore, the load of the scribing wheel 32 when forming the second crack 5b (e.g., about 1.5 N) is smaller than the load of the scribing wheel 32 when forming the first crack 5a (e.g., about 2.0 N). Therefore, when the second crack 5b is formed, the stress caused by the difference between the formed direction of the second crack 5b and the pressing direction of the scribing wheel 32 is reduced. In FIGS. 6A and 6B, regions Ra and Rb each indicate the compressive stress generated inside the semiconductor wafer 2 due to the pressure applied by the scribing wheel 32. As shown in FIGS. 6A and 6B, since the load of the scribing wheel 32 when forming the second crack 5b is smaller than the load of the scribing wheel 32 when forming the first crack 5a, the range of the region Rb (i.e., the magnitude of compressive stress) can be made substantially equal to the range of the region Ra. As such, it is possible to reduce the residual stress in the entire semiconductor device 10 to be manufactured.

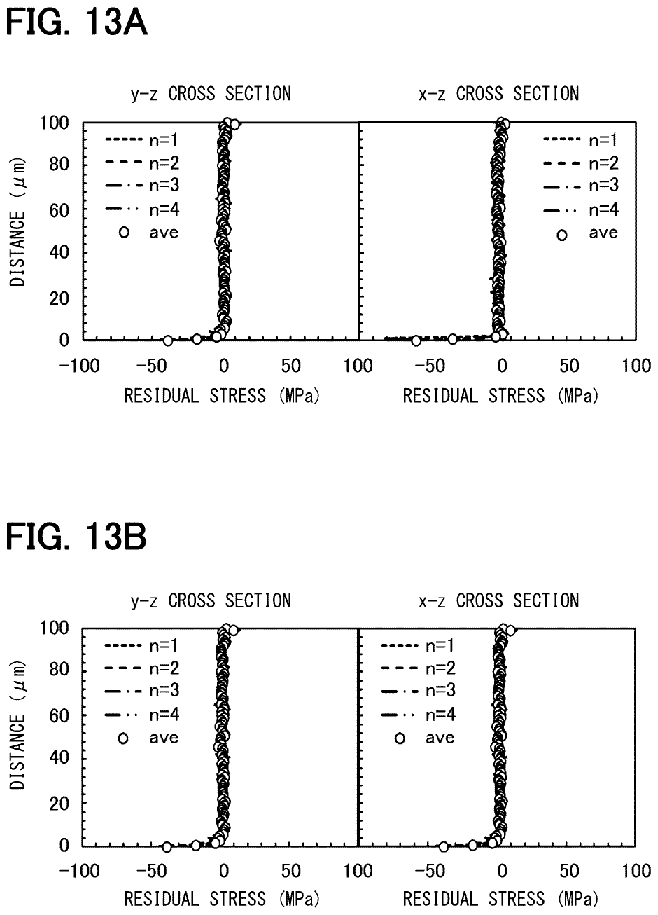

FIG. 13A is a graph showing the measurement results of the residual stress in the semiconductor device of the comparative example. FIG. 13B is a graph showing the measurement results of the residual stress in the semiconductor device of the present embodiment. In FIGS. 13A and 13B, the horizontal axis represents the value of residual stress, and the vertical axis represents the distance from the dividing surface (i.e., the surface pressed by the scribing wheel). In regard to the residual stress, the tensile stress is indicated by a positive value and the compressive stress is indicated by a negative value. In the comparative example, the load of the scribing wheel 32 when forming the first crack 5a is substantially equal to the load of the scribing wheel 32 when forming the second crack 5b. As described above, in the x-z cross section, the crystal axis A is inclined relative to the pressing direction of the scribing wheel 32. Therefore, in the semiconductor device of the comparative example, as shown in FIG. 13A, a large residual stress (about 84 MPa) is present near the dividing surface (i.e., near the crack). On the other hand, in the semiconductor device 10 of the present embodiment, since the load of the scribing wheel 32 when forming the second crack 5b smaller than the load of the scribing wheel 32 when forming the first crack 5a, the residual stress in the x-z cross section can be reduced to a value equivalent to the residual stress in the y-z cross section (about 55 MPa), as shown in FIG. 13B. According to the manufacturing method of the present embodiment, the residual stress in the entire semiconductor device 10 is reduced, and a highly reliable semiconductor device 10 can be obtained.

In the present embodiment, the element structures 6 are formed not on the first surface 2a side against which the scribing wheel 32 is pressed, but on the second surface 2b located on the rear side of the first surface 2a. Therefore, even if the residual stress exists on the first surface 2a side, it is possible to reduce the influence on the element structures 6 that realize the functions of the manufactured semiconductor devices 10.

In the embodiment described above, the support plate attaching process, the dicing tape attaching process, and the protective member covering process may be omitted. Further, the metal film forming process may be performed before the first crack forming process and the second crack forming process, or may not be performed. That is, in the technology disclosed in this specification, at least the first crack forming process, the second crack forming process, and the dividing process are performed on the semiconductor wafer whose crystal axis is inclined relative to the perpendicular line to the surface of the semiconductor wafer.

While only the exemplary embodiment and examples have been chosen to illustrate the present disclosure, it will be apparent to those skilled in the art from this disclosure that various changes and modifications can be made therein without departing from the scope of the disclosure as defined in the claims. Furthermore, the foregoing description of the exemplary embodiment and examples according to the present disclosure is provided for illustration only, and not for the purpose of limiting the disclosure as defined by the appended claims and their equivalents. The technical elements described in this specification or drawings exhibit technical usefulness alone or in various combinations, and are not limited to the combinations described in the claims at the time of filing. In addition, the techniques illustrated in this specification or drawings achieve multiple objectives at the same time, and achieving one of the objectives itself has technical usefulness.

What is claimed is:

1. A method for manufacturing a semiconductor device, comprising:
preparing a semiconductor wafer having a first surface and a second surface opposite to the first surface in a thickness direction of the semiconductor wafer, the semiconductor wafer having a crystal axis inclined relative to a perpendicular line to the first surface;
forming a first crack in the semiconductor wafer to extend along a first direction and in the thickness direction by pressing a pressing member against the first surface with a first load and along the first direction, the first direction being along an inclined direction of the crystal axis on the first surface;
forming a second crack in the semiconductor wafer to extend along a second direction and in the thickness direction by pressing the pressing member against the first surface with a second load smaller than the first load and along the second direction, the second direction being perpendicular to the first direction on the first surface; and
dividing the semiconductor wafer along the first crack and the second crack by pressing a dividing member against the semiconductor wafer on a side of the second surface in the thickness direction and along the first crack and the second crack.

2. The method according to claim 1, further comprising:
before the forming of the first crack and the forming of the second crack, forming a plurality of element structures in a matrix on the second surface of the semiconductor wafer, wherein
in the forming of the first crack and the forming of the second crack, the first crack and the second crack are formed along boundaries between the plurality of element structures.

3. The method according to claim 1, further comprising:
after the forming of the first crack and the forming of the second crack and before the dividing of the semiconductor wafer, forming a metal film on the first surface of the semiconductor wafer.

4. The method according to claim 1, wherein the semiconductor wafer is made of silicon carbide.

5. The method according to claim 4, wherein the crystal axis is a c-axis.
